(19) United States
(12) Patent Application Publication
(10) Pub. No.: US 2025/0385481 A1
(43) Pub. Date: Dec. 18, 2025

(54) NARROW TYPE AND LOW LIGHT LOSS LASER OPTICAL MODULE

(71) Applicant: PPTEK OPTOELECTRONICS CORPORATION, Taipei City (TW)

(72) Inventors: Tsung Hsueh HAN, Taipei City (TW); Wen Cheng CHANG, Yilan County (TW)

(73) Assignee: PPTEK OPTOELECTRONICS CORPORATION, Taipei City (TW)

(21) Appl. No.: 18/742,478

(22) Filed: Jun. 13, 2024

(51) Int. Cl. H01S 5/02212; H01S 5/00; H01S 5/02257

(52) U.S. Cl. CPC H01S 5/02212; H01S 5/02257; H01S 5/0014

(57) ABSTRACT

A narrow type and low light loss laser optical module comprising: a base, which having a laser diode and a photodiode chip; wherein: a narrow shape tube, the diameter of the bottom of the narrowed shape tube is smaller than the base, and is covering the outer periphery of the fixed base, the top of the narrowed shape tube is provided with a through opening without a cover; an optical glass inserted from above the through opening and fixed on the accepting surface, so as to form a narrow type laser optical module; and the height of the narrow shape tube is set based on the optical characteristics of the optical glass and the focal length required by the narrow type laser optical module.

### BACKGROUND OF THE INVENTION

### 1. Field of the Invention

The present invention relates to a narrow type and low light loss laser optical module especially the one that has a convenient manufacturing process, can reduce light loss, and can produce a laser optical module which volume is smaller and narrower.

### 2. Description of the Related Art

Since the invention of laser diodes (LD), it has been used in many fields such as optical communications, optical recording and optical storage. Laser diodes (LD) come in two types: edge-emitting and surface-emitting. Among them, surface-emitting LD must be packaged to prevent dust and eliminate the impact of ambient temperature changes on its performance to ensure the stability of products.

The commonly used LD packaging method adopts TO-CAN structure, and its structure is showing in FIGS. 1A and 1B. The LD package includes: a base 11, multiple electrical connection terminals 12, a photodetector 13, a laser 14, a packaging cover 15, the top surface of which is provided with a light outlet 151 and a protective glass 16 for sealing the light outlet 151 to prevent dust from entering. Also, the LD package forms a laser point emitter 10a, and the laser beam L can be projected from the protective glass 16 above the packaging cover 15. However, it is found that the protective glass 16 needs to be pushed upward from the bottom of the packaging cover 15 to the bottom of the light outlet 151 before being packaged, and then to be bonded and fixed, which is inconvenient and time-consuming during manufacturing process.

Moreover, the function of the laser point emitter 10a is to emit the laser beam L. As shown in FIGS. 2A and 2B, when it reaches the application end, requires a shell 10b to be packaged externally, an optical lens 17 is provided at the front end of the shell 10b, so as to form a laser optical module 10 with required optical function. However, the shell 10b of this conventional laser optical module 10 is installed on the periphery of the base 11. In the above-mentioned light source structure, the work distance between the laser 14 and the optical lens 17 (such as a collimating lens) is specific and requires high accuracy, thus increasing process and assembly costs. In addition, the laser optical module 10 needs to be packaged in a shell 10b, the diameter (D4) of which is much larger than the base diameter (D1) of the laser point emitter 10a, so that the overall length or thickness is huge, for example: the most commonly used specification of TO-CAN is 5.6 mmφ, the diameter (D2) of the package cover 15 is about 4 to 4.5 mmφ, and the diameter (D1) of the base 11 is 5.6 mm. In this way, the base 11 plus the shell 10b, the diameter is at least more than 10 mmφ, so the volume becomes large and takes up space. Therefore, it is difficult to accommodate it on a thin and light mobile device. Furthermore, after the laser beam L passes through the protective glass 16 of the first layer and then is projected to the optical lens 17 of the second layer, it needs to pass through two layers of materials, resulting in light loss, these are all its shortcomings.

### SUMMARY OF THE INVENTION

A primary objective of the present invention is to provide a narrow type and low light loss laser optical module that having a convenient manufacturing process, reducing light loss, and making the volume smaller and narrower, thereby improving the efficiency of being accommodated in thin and light electronic devices.

To achieve the objective mentioned above, the present invention comprises: a base, which is configured in the form of a lead frame of a TO-CAN package, and having a plurality of electrical connection terminals extending downward; a laser diode arranged on a fixed base above the base; a photodiode chip arranged on the light emitting surface of the laser diode for detecting laser power; wherein: a narrow shape tube, the diameter of the upper half of which is smaller than the diameter of the lower half, the diameter of the bottom of the narrowed shape tube is smaller than the base, and is covering the outer periphery of the fixed base to be arranged on the surface of the base; also the top of the narrowed shape tube is provided with a through opening without a cover, its overall height is higher than the packaging cover of the traditional TO-CAN structure, and forms an accepting surface at the inner wall of the top opening of the through opening; an optical glass inserted from above the through opening and fixed on the accepting surface for making the installation of the optical glass not cause the narrow shape tube to interfere with the base and the laser beam emitted by the laser diode, so as to form a narrow type laser optical module; and the height of the narrow shape tube is set based on the optical characteristics of the optical glass and the focal length required by the narrow type laser optical module.

Also, the optical glass includes a diffractive optical lens or an optical lens.

Also, the cross section of the accepting surface presents an L-shaped body to support the optical glass to be fixed on the top opening of the through opening.

Also, the tube diameter of the upper half of the narrowed shape tube is between 0.6 and 0.8 of the tube diameter of the lower half.

Also, the height of the narrowed shape tube is 7˜12 mm.

With structures disclosed above, the narrowed shape tube plus optical glass can form a TO-CAN packaging cover and the outer shell for adjusting the optical focal length, that has a convenient manufacturing process, can reduce light loss, and can make the volume smaller and narrower, thereby making it possible to be accommodated in thinner and lighter electronic devices.

### BRIEF DESCRIPTION OF THE DRAWINGS

FIG. 1A is a schematic diagram of the conventional laser diode package;

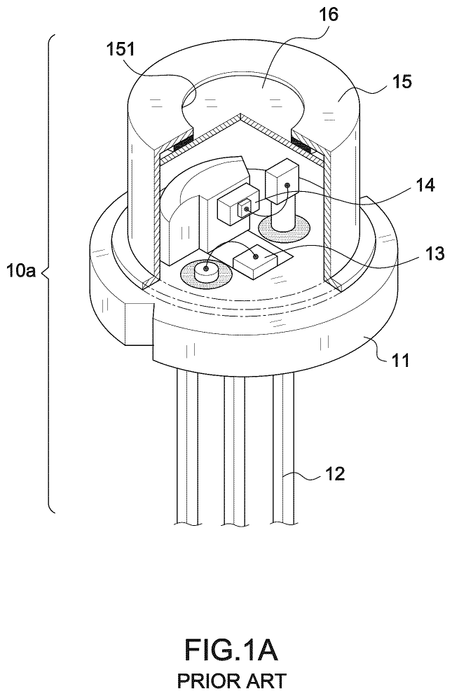

FIG. 1B is a sectional view of the conventional laser diode package;

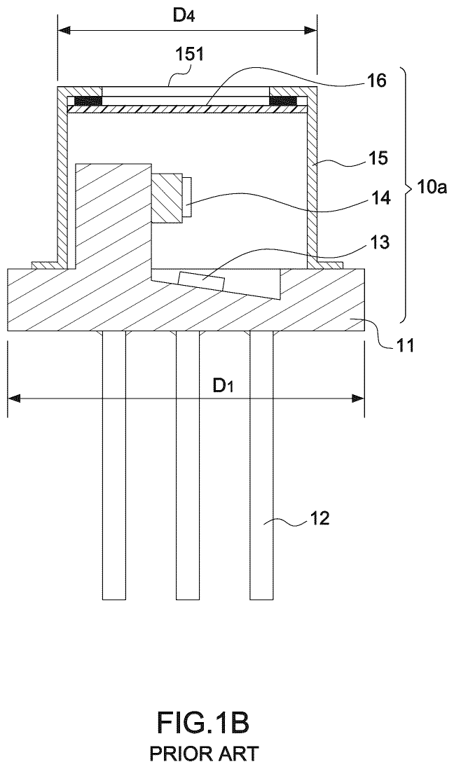

FIG. 2A is an exploded perspective view of conventional laser point emitter;

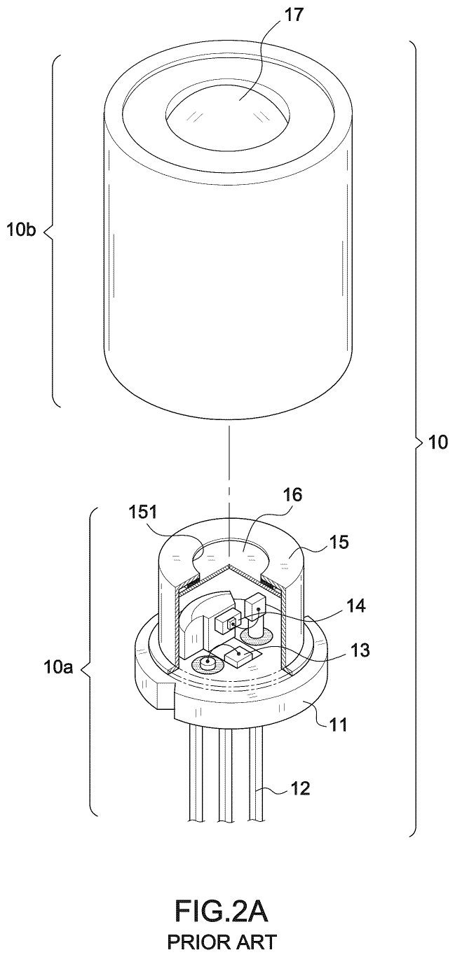

FIG. 2B is an assembly perspective view of conventional laser point emitter;

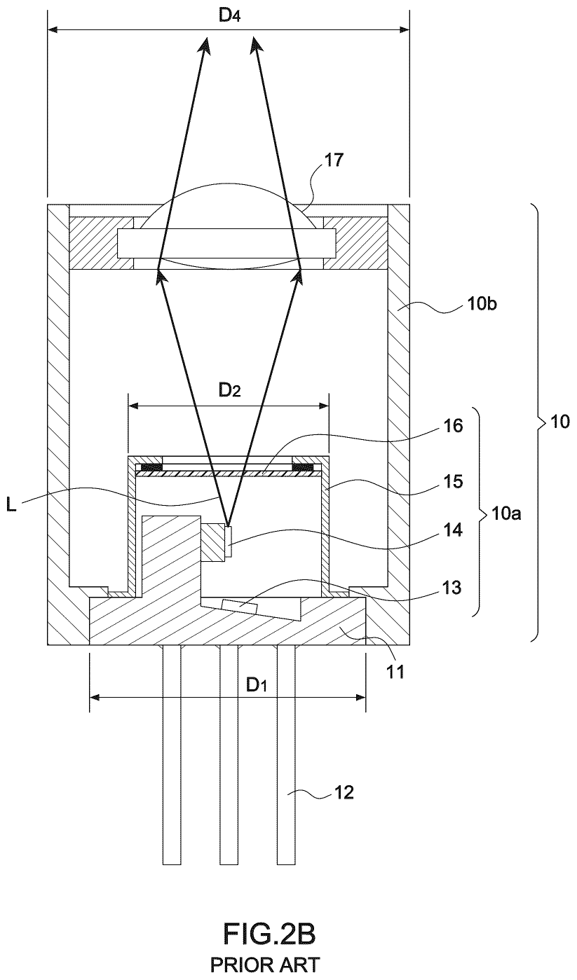

FIG. 3 is an exploded perspective view of the preferred embodiment of the present invention;

FIG. 4 is an assembly perspective view of the preferred embodiment of the present invention;

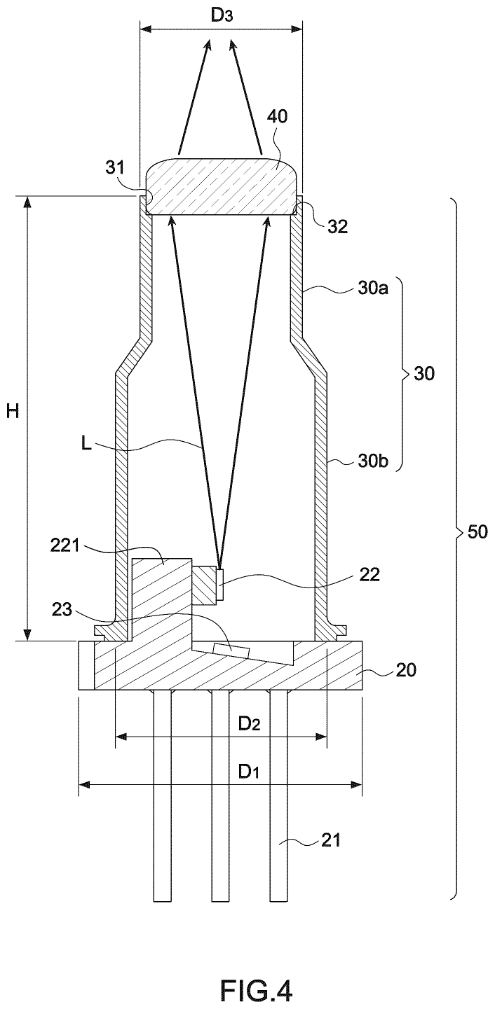

FIG. 5 is a schematic diagram illustrating the comparison between the prior art and the present invention.

### DETAILED DESCRIPTION OF THE PREFERRED EMBODIMENT

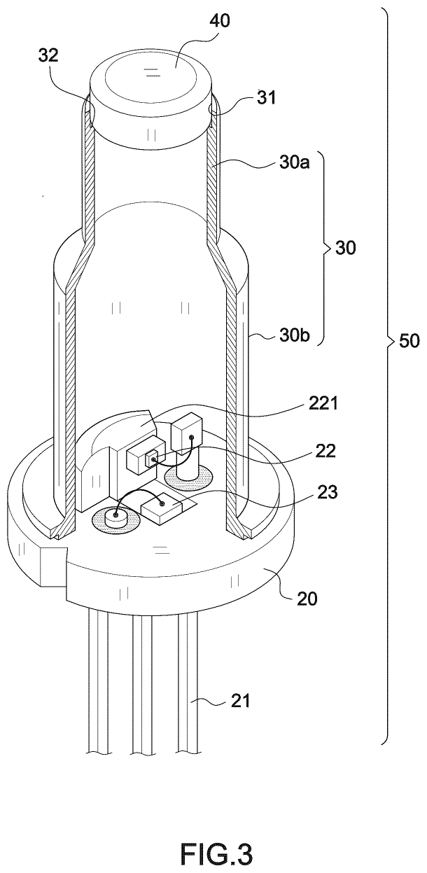

Referring to FIGS. 3˜5, a preferred embodiment of the present invention includes: a base 20, which is configured in the form of a lead frame of a TO-CAN package, and having a plurality of electrical connection terminals 21 extending downward; a laser diode 22 arranged on a fixed base 221 above the base 20; a photodiode chip 23 arranged on the light emitting surface of the laser diode 22 for detecting laser power; These feature technique belongs to the prior art, which are not the main features of the present invention, so there are not disclosed in detail.

The main features of the present invention are: a narrow shape tube 30, the diameter D3 of the upper half 30a of which is smaller than the diameter D2 of the lower half 30b, the diameter D2 of the bottom of the narrowed shape tube 30 is smaller than the base 20, and is covering the outer periphery of the fixed base 221 to be arranged on the surface of the base 20; also the top of the narrowed shape tube 30 is provided with a through opening 31 without a cover, its overall height is higher than the packaging cover of the traditional TO-CAN structure, and forms an accepting surface 32 at the inner wall of the top opening of the through opening 31; in this embodiment, the diameter D3 of the upper half 30a of the narrowed shape tube 30 is between 0.6 and 0.8 of the tube diameter D2 of the lower half.

An optical glass 40 inserted from above the through opening 31 and fixed on the accepting surface 32, since the diameter of the optical glass 40 (slightly smaller than D3) does not need to be as large as the diameter D2 of the bottom of the narrowed shape tube 30, the through opening 31 can be smaller than the diameter of the bottom of the narrowed shape tube 30, which only needs to be slightly larger than the diameter of the optical glass 40 for installation, therefore, the through opening 31 of the upper half 30a of the narrowed shape tube 30 can be used for inserting and fixing the optical glass 40, and the diameter D2 of the lower half 30b can be just enough to be sleeve on the base 20 and covering the outer periphery of the fixed base 221, so the installation of the optical glass 40 will not cause the narrow shape tube 30 to interfere with the base 20 and the laser beam L emitted by the laser diode 22, so as to form a narrow type laser optical module 50; and the height H of the narrow shape tube 30 is set based on the optical characteristics of the optical glass 40 and the focal length required by the narrow type laser optical module 50. In this embodiment, the optical glass 40 includes a diffractive optical lens or an optical lens.

In this embodiment, the cross section of the accepting surface 32 presents an L-shaped body to support the optical glass 40 to be fixed on the top opening of the through opening 31.

With structures disclosed above, instead of having the shell 10b and the protective glass 16 in prior art, the present invention uses the narrowed shape tube 30 plus optical glass 40 to form a TO-CAN packaging cover and the outer shell for adjusting the optical focal length, that has a convenient manufacturing process, can reduce light loss, and can make the volume smaller and narrower, thereby making it possible to be accommodated in thinner and lighter electronic devices.

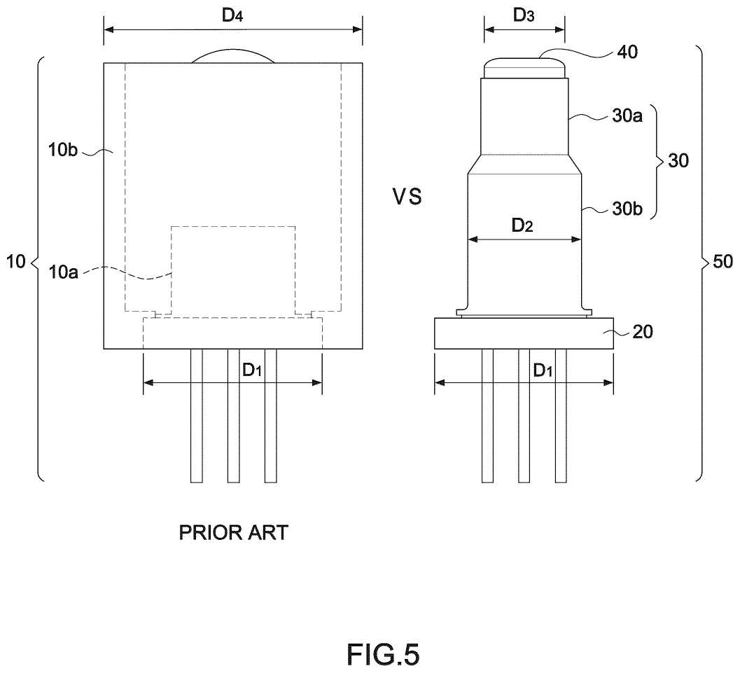

Referring to FIG. 5, the comparison of prior art and the present invention, the current specifications of TO-CAN are: 3.8 mmφ, 5.6 mmφ, 9.0 mmφ. Take most commonly used diameter D1, 5.6 mmφ, of the base 11 for example, then adds with the shell 10b, the diameter is at least more than 10 mmφ, thus making the volume large and occupying space. On the other hand, the diameter D1 of the base 20 of the present invention is also 5.6 mmφ, the diameter D2 of the lower half 30b of the narrowed shape tube 30 is about 4˜4.5 mmφ, and the diameter D3 of the upper half 30a is about 4 about 2.5˜3.5 mmφ, the height H is set based on the optical characteristics of the optical glass 40 and the focal length required by the narrow type laser optical module 50, which is about 7˜12 mm, but not limited to this. As a result, the laser optical module 50 of the present invention is at least several times smaller than the laser optical module 10 of the prior art, thereby making the overall shape narrower and more suitable for thin and light mobile devices or electronic devices.

The present invention has the following effects that need further elucidation:

1. The narrow type laser optical module 50 of the present invention does not require the packaging cover 15, protective glass 16 and shell 10b of the prior art. The protective glass 16 needs to be pushed upward from the bottom of the packaging cover 15 to the bottom of the light outlet 151 before being packaged, and then to be bonded and fixed, which is inconvenient and time-consuming during manufacturing process. The present invention only requires the narrowed shape tube 30 and the optical glass 40, which are also the packaging cover of TO-CAN and the outer shell for adjusting the optical focal length, that has a convenient manufacturing process, can reduce light loss, and reduce the material and assembly costs of the entire module.

2. The optical glass 40 inserted from above the through opening 31 and fixed on the accepting surface 32, not only is it easy to assemble, but also when the height H of the narrowed shape tube 30 is set according to the desired focal length, the height of the optical glass 40 will be accurately positioned, thereby improving the effect of obtaining accurate focal length.

3. The narrow type laser optical module 50 of the present invention is at least several times smaller in volume than the laser optical module 10 of the prior art, thereby making the overall shape narrower and more suitable for thin and light mobile devices or electronic devices, so it has wider application then prior art.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A narrow type and low light loss laser optical module comprising:
a base, which is configured in the form of a lead frame of a TO-CAN package, and having a plurality of electrical connection terminals extending downward;
a laser diode arranged on a fixed base above the base;
a photodiode chip arranged on the light emitting surface of the laser diode for detecting laser power;
wherein:
a narrow shape tube, the diameter of the upper half of which is smaller than the diameter of the lower half, the diameter of the bottom of the narrowed shape tube is smaller than the base, and is covering the outer periphery of the fixed base to be arranged on the surface of the base; also the top of the narrowed shape tube is provided with a through opening without a cover, its overall height is higher than the packaging cover of the traditional TO-CAN structure, and forms an accepting surface at the inner wall of the top opening of the through opening;
an optical glass, inserted from above the through opening and fixed on the accepting surface for making the installation of the optical glass not cause the narrow shape tube to interfere with the base and the laser beam emitted by the laser diode, so as to form a narrow type laser optical module; and
the height of the narrow shape tube is set based on the optical characteristics of the optical glass and the focal length required by the narrow type laser optical module.

2. The narrow type and low light loss laser optical module as claimed in claim 1, wherein the optical glass includes a diffractive optical lens or an optical lens.

3. The narrow type and low light loss laser optical module as claimed in claim 1, wherein the cross section of the accepting surface presents an L-shaped body to support the optical glass to be fixed on the top opening of the through opening.

4. The narrow type and low light loss laser optical module as claimed in claim 1, wherein the tube diameter of the upper half of the narrowed shape tube is between 0.6 and 0.8 of the tube diameter of the lower half.

5. The narrow type and low light loss laser optical module as claimed in claim 4, wherein the height of the narrowed shape tube is 7˜12 mm.
